(19) United States
(12) Patent Application Publication
(10) Pub. No.: US 2007/0031764 A1
(43) Pub. Date: Feb. 8, 2007

(54) EXPOSURE PROCESS

(76) Inventors: Meng-Chi Liou, Taoyuan County (TW); Fu-Yuan Shiau, Chiayi City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,430

(22) Filed: Aug. 3, 2005

(51) Int. Cl. G03F 7/20

(52) U.S. Cl. 430/322; 430/311

(57) ABSTRACT

An exposure process is provided. First, a plurality of optical modules is provided. The optical modules are arranged in order and a partially overlap areas is formed at the overlapping region between each two adjacent optical modules. A photo mask with pluralities of first device patterns and pluralities of second device patterns thereon is provided and disposed under the optical modules. The locations of the first device patterns are corresponding to the partially overlap areas, and the locations of the second device patterns are corresponding to the other area. In particular, the first device patterns have a dimension different from that of the second device patterns. A photo resist layer is provided under the photo mask. The optical modules and the photo mask are used to perform an exposure step to transfer the first device patterns and the second device patterns to the photo resist layer.

### BACKGROUND OF THE INVENTION

1. Field of the Invention

The present invention relates to an exposure process. More particularly, the present invention relates to an exposure process for improving the uniformity of the patterns formed in the exposure process.

2. Description of Related Art

With the development of the video technology, the flat display panels (FDP) have become the major interfaces for image information receiving. Wherein, because of the excellent display performance and accomplished fabricating technique of the liquid crystal display (LCD), the LCD panels are generally used in most of the monitors of the mobile phones, the digital cameras and the laptops. Moreover, with the increasing demand in LCD TV, the LCD panels are being developed for larger sizes.

Generally, the fabricating process of the thin film transistor (TFT) array substrates of the liquid crystal display includes repeatedly photolithography steps and etching steps. In other words, the TFT array substrate is manufactured by performing the following steps. First, the exposure process is performed to transform the patterns of a photo mask to the positive photo resist layer formed on a substrate, and the development process is performed to pattern the photo resist layer. Thereafter, another etching process is carried out to etch the film layer under the positive photo resist layer by using the patterned positive photo resist layer as an etching mask. With repeatedly performing the forgoing processes, the gates, the channels, the sources/drains, the pixel electrodes and the passivation layers of the TFTs can be formed.

However, the large-scale photolithography apparatus is necessary for performing large size scan in the exposure process of the fabricating of the large size LCDs. Consequently, the optical modules in the large-scale photolithography apparatus must satisfy the accuracy of the exposure process of the fabricating of the large size LCDs. Else, the character of the fabricated TFTs (such as the capacitor between the gate and the drain Cgd) will be influenced.

The optical module in the conventional exposure apparatus is consisted of a unitary optical module with large size or pluralities of optical modules with small size. During performing the exposure step by using the unitary optical module with large size, the pattern distortion often happened with the diffraction in the edge of the large size optical module. Therefore, the pluralities of small size optical modules are commonly used in the exposure apparatus. However, some disadvantages still exist in the exposure apparatus with pluralities of small size optical modules.

FIG. 1 is a schematic drawing of an exposure apparatus. Referring to FIG. 1, an exposure apparatus 100 includes a plurality of optical modules 110 with small size and a photo mask 120. The optical modules 110 are arranged in zigzag, and the photo mask 120 is disposed under the optical modules 110. By the scan and the exposure of the optical modules 110 and the photo mask 120 in X-Y plane, the patterns on the photo mask 120 can be transferred to a positive photo resist layer 130 on a substrate 140 that locates under the photo mask 120. However, the exposure mura (such as lens mura) shown in FIGS. 2A and 2B will occur in the exposure process proceeded with the plurality of small size optical module 110 and the photo mask 120.

FIGS. 2A and 2B are schematic drawings of two kinds of exposure mura produced in the exposure process with using the exposure apparatus of FIG. 1.

Referring to FIG. 2A, the overlapping region between two adjacent optical modules 110 is a partially overlap areas 112. Because of the different transmittance of the optical modules 110 in the partially overlap areas 112 and the other non-overlapping region, the exposure intensity in the partially overlap areas 112 will be higher or lower than the exposure intensity in the other non-overlapping region. Consequently, the areas 132 that exposed overly or exposed insufficiently may exhibit in the partially overlap areas 112.

Especially, since the optical modules 110 is hanged above the photo mask 120 by a supporting mechanism, the central optical module 110a will slightly sink along the Z direction. Consequently, the areas 132 that exposed overly or exposed insufficiently exhibit easily in the partially overlap areas 112 beside the optical module 110a after the exposure for the positive photo resist layer 130. The exposure effects in the areas 132 of the positive photo resist layer 130 are apparently different from others, such that the device patterns (such as patterns of TFTs) formed in areas 132 will be different from others, and the operating characters of the elements formed by said exposure process will be different from each other.

Referring to FIGS. 1 and 2B, another exposure mura is caused by the slight sinking along the Z direction of the optical module 110a in central position of the supporting mechanism. Owing to the slight sinking of the optical module 110a, the exposure intensity corresponding to the optical module 110a will be higher or lower. In other words, the exposure intensity in the central area 114 of the optical module 110a will be different from others. Consequently, the area 134 that exposed overly or exposed insufficiently will exhibit in the position of the positive photo resist layer 130 corresponding to the central area 114. The exposure effects in the area 134 is apparently different from others, such that the operating characters of the elements formed by said exposure process will be different from each other.

Naturally, the exposure mura shown in FIGS. 2A and 2B may happen in the same time. Otherwise, the exposure mura existed in the scan-type exposure will be worse with the increasing size of the display panel.

### SUMMARY OF THE INVENTION

Accordingly, the present invention is directed to an exposure process for forming the uniformity of the whole exposure patterns and improving the display quality of the LCDs.

The present invention provides an exposure process. In the exposure process, a plurality of optical modules is provided first. The optical modules are arranged in order, and a partially overlap area is formed between each two adjacent optical modules. Then, a photo mask is provided under the optical modules. The photo mask has a plurality of first device patterns and a plurality of second device patterns. The locations of the first device patterns of the photo mask are corresponding to the partially overlap areas, and the locations of the second device patterns of the photo mask are corresponding to the other area. Wherein, parts of the first device patterns have dimensions different from that of the second device patterns. Thereafter, a photo resist layer is provided under the photo mask. Afterward, an exposure step is performed with using the optical modules and the photo mask to transfer the first device patterns and the second device patterns to the photo resist layer.

According to an embodiment of the present invention, if the photo resist layer is positive photo resist, and the exposure intensity corresponding to the partially overlap areas is higher than the exposure intensity corresponding to the other areas in the exposure step of the exposure process, the dimensions of part of the first device patterns corresponding to the partially overlap areas can be designed to be larger than the dimensions of the second device patterns. Wherein, the first device patterns corresponding to the partially overlap areas may include a plurality of first patterns and a plurality of second patterns arranged randomly. The dimensions of the second patterns could be the same with the dimensions of the second device patterns, and the dimensions of the first patterns could be larger than the dimensions of the second patterns.

According to another embodiment of the present invention, if the photo resist layer is positive photo resist, and the exposure intensity corresponding to the partially overlap areas is lower than the exposure intensity corresponding to the other areas in the exposure step of the exposure process, the dimensions of part of the first device patterns corresponding to the partially overlap areas can be designed to be smaller than the dimensions of the second device patterns. Wherein, the first device patterns corresponding to the partially overlap areas may include a plurality of first patterns and a plurality of second patterns arranged randomly. The dimensions of the second patterns could be the same with the dimensions of the second device patterns, and the dimensions of the first patterns could be smaller than the dimensions of the second patterns.

According to an embodiment of the present invention, if the photo resist layer is negative photo resist, and the exposure intensity corresponding to the partially overlap areas is higher than the exposure intensity corresponding to the other areas in the exposure step of the exposure process, the dimensions of part of the first device patterns corresponding to the partially overlap areas can be designed to be smaller than the dimensions of the second device patterns. Wherein, the first device patterns corresponding to the partially overlap areas may include a plurality of first patterns and a plurality of second patterns arranged randomly. The dimensions of the second patterns could be the same with the dimensions of the second device patterns, and the dimensions of the first patterns could be smaller than the dimensions of the second patterns.

According to another embodiment of the present invention, if the photo resist layer is negative photo resist, and the exposure intensity corresponding to the partially overlap areas is lower than the exposure intensity corresponding to the other areas in the exposure step of the exposure process, the dimensions of part of the first device patterns corresponding to the partially overlap areas can be designed to be larger than the dimensions of the second device patterns. Wherein, the first device patterns corresponding to the partially overlap areas may include a plurality of first patterns and a plurality of second patterns arranged randomly. The dimensions of the second patterns could be the same with the dimensions of the second device patterns, and the dimensions of the first patterns could be larger than the dimensions of the second patterns.

According to still another embodiment of the present invention, the first device patterns and the second device patterns could be the pixel patterns of a liquid crystal display.

The present invention provides another exposure process. In the exposure process, a plurality of optical module is provided first. Then, a photo mask is provided under the optical module. Wherein, at least one of the optical modules is correspondingly disposed in a central area of the photo mask. The photo mask has a plurality of first device patterns and a plurality of second device patterns. The first device patterns are disposed in the central area of the photo mask, and the second device patterns are disposed in the other area of the photo mask. The dimensions of parts of the first device patterns is different from the dimensions of the second device patterns. Thereafter, a photo resist layer is provided under the photo mask. Afterward, an exposure step is performed with using the optical modules and the photo mask to transfer the first device patterns and the second device patterns to the photo resist layer.

According to an embodiment of the present invention, if the photo resist layer is positive photo resist, and the exposure intensity corresponding to the central areas is higher than the exposure intensity corresponding to the other areas in the exposure step of the exposure process, the dimensions of part of the first device patterns corresponding to the central areas could be designed to be larger than the dimensions of the second device patterns. Wherein, the first device patterns corresponding to the central areas may include a plurality of first patterns and a plurality of second patterns arranged randomly. The dimensions of the second patterns could be the same with the dimensions of the second device patterns, and the dimensions of the first patterns could be larger than the dimensions of the second patterns.

According to another embodiment of the present invention, if the photo resist layer is positive photo resist, and the exposure intensity corresponding to the central areas is lower than the exposure intensity corresponding to the other areas in the exposure step of the exposure process, the dimensions of part of the first device patterns corresponding to the central areas could be designed to be smaller than the dimensions of the second device patterns. Wherein, the first device patterns corresponding to the central areas may include a plurality of first patterns and a plurality of second patterns arranged randomly. The dimensions of the second patterns could be the same with the dimensions of the second device patterns, and the dimensions of the first patterns could be smaller than the dimensions of the second patterns.

According to an embodiment of the present invention, if the photo resist layer is negative photo resist, and the exposure intensity corresponding to the central areas is higher than the exposure intensity corresponding to the other areas in the exposure step of the exposure process, the dimensions of part of the first device patterns corresponding to the central areas could be designed to be smaller than the dimensions of the second device patterns. Wherein, the first device patterns corresponding to the central areas may include a plurality of first patterns and a plurality of second patterns arranged randomly. The dimensions of the second patterns could be the same with the dimensions of the second device patterns, and the dimensions of the first patterns could be smaller than the dimensions of the second patterns.

According to another embodiment of the present invention, if the photo resist layer is negative photo resist, and the exposure intensity corresponding to the central areas is lower than the exposure intensity corresponding to the other areas in the exposure step of the exposure process, the dimensions of part of the first device patterns corresponding to the central areas could be designed to be larger than the dimensions of the second device patterns. Wherein, the first device patterns corresponding to the central areas may include a plurality of first patterns and a plurality of second patterns arranged randomly. The dimensions of the second patterns could be the same with the dimensions of the second device patterns, and the dimensions of the first patterns could be larger than the dimensions of the second patterns.

According to still another embodiment of the present invention, the first device patterns and the second device patterns could be the pixel patterns of a liquid crystal display.

By the use of the photo mask that has the device patterns with different dimensions randomly distributed thereon, the device patterns with different dimensions can be transferred to the photo resist layer, and the devices with different dimensions can be formed on the partially overlap areas or the central area where the exposure intensities of the optical modules are different from vicinity. Such that, the uniformity of the device patterns formed in the exposure process can be improved, and the display quality of the LCDs could also be improved without any increase of cost.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic drawing of an exposure apparatus.

FIGS. 2A and 2B are schematic drawings of two kinds of exposure mura produced in the exposure process with using the exposure apparatus of FIG. 1.

FIG. 3A is a schematic drawing of an exposure process according to an embodiment of the present invention.

FIG. 3B is a top view of a photo mask in an embodiment of the present invention.

FIGS. 4A and 4B are schematic drawings of the linear random arrangements of the first patterns and the second patterns.

FIG. 5 is a schematic drawing of the mosaic arrangement of the first patterns and the second patterns.

FIG. 6A is a schematic drawing of an exposure process according to another embodiment of the present invention.

FIG. 6B is a top view of a photo mask in another embodiment of the present invention.

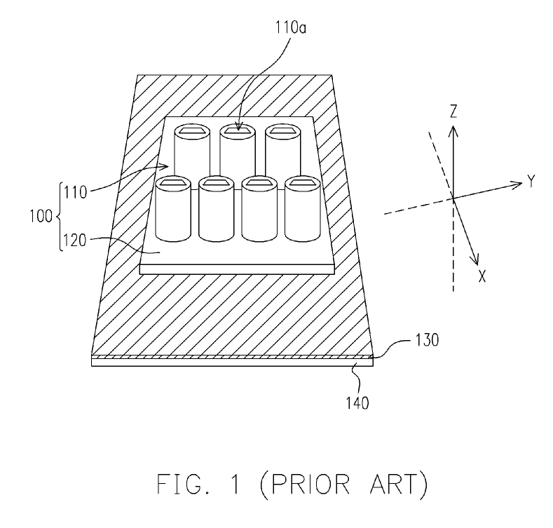

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

For solving the defects caused by said two kinds of exposure mura, a photo mask with different patterns (such as different dimensions) is used to compensate for the exposure mura, such that the uniform patterns can be obtained.

### First Embodiment

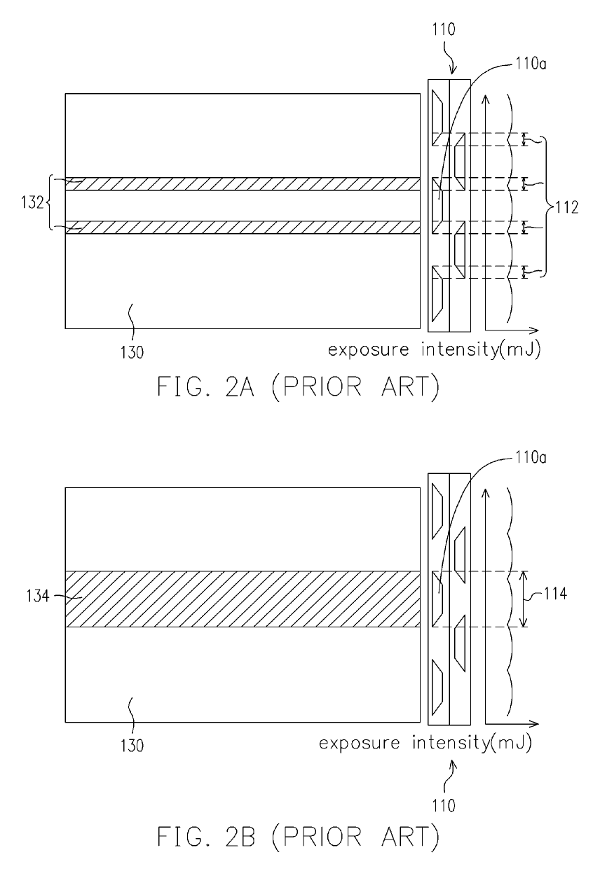

The present invention provides an exposure process to eliminate the areas 132 that exposed overly or exposed insufficiently shown in FIG. 2A.

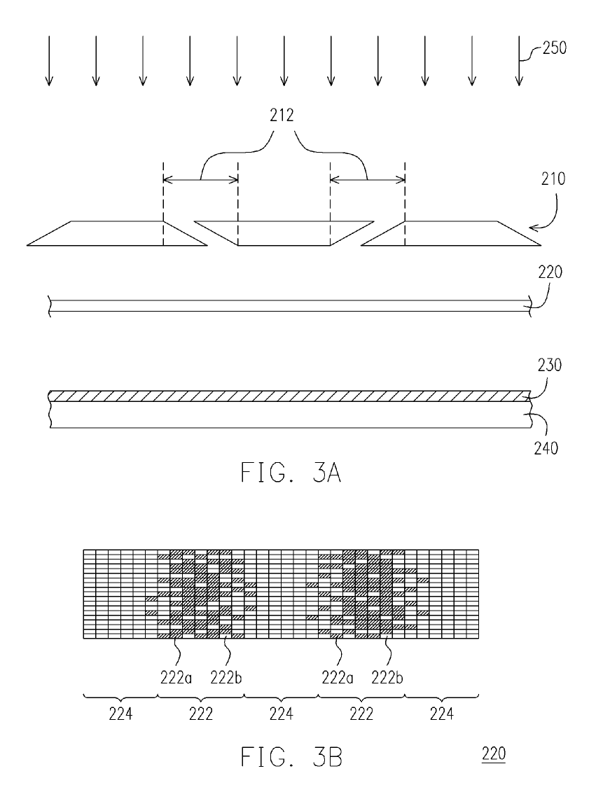

FIG. 3A is a schematic drawing of an exposure process according to an embodiment of the present invention, and FIG. 3B is a top view of a photo mask in an embodiment of the present invention. Referring to FIGS. 3A and 3B, a plurality of optical modules 210 can be provided first in this exposure process. The optical modules 210 might be arranged in several lines, and the optical modules 210 in different lines are staggered to each other. A partially overlap area 212 is formed at the overlapping region between each two adjacent optical modules 210.

Thereafter, a photo mask 220 is provided under the optical modules 210. As shown in FIG. 3B, the photo mask 220 has a plurality of first device patterns 222 and a plurality of second device patterns 224. The first device patterns 222 of the photo mask 220 are disposed correspondingly to the partially overlap areas 212, and the second device patterns 224 are disposed on the other region of the photo mask 220. Wherein, parts of the first device patterns 222 have dimensions different from that of the second device patterns 224.

Then, a photo resist layer 230 is provided under the photo mask 220. The photo resist layer 230 can be positive type or negative type. Afterward, an exposure step 250 is performed for the photo resist layer 230 with using the optical modules 210 and the photo mask 220 to transfer the first device patterns 222 and the second device patterns 224 to the photo resist layer 230. In one preferred embodiment of this invention, the first device patterns 222 and the second device patterns 224 might be the pixel patterns of the LCDs, such as the patterns of the gates, the sources/drains or the pixel electrodes of the TFTs.

In one embodiment of this invention, if the photo resist layer 230 is positive photo resist, and the exposure intensity corresponding to the partially overlap areas 212 is higher than the exposure intensity corresponding to the other areas in the exposure step 250, the dimensions of part of the first device patterns 222 corresponding to the partially overlap areas 212 will be designed to be larger than the dimensions of the second device patterns 224. Because of the formed patterns in the partially overlap areas 212 will be smaller with higher exposure intensity, the device patterns corresponding to the partially overlap areas 212 should be designed with larger dimensions to compensate the shrink of the device patterns caused by the higher exposure intensity.

Referring to FIGS. 3A and 3B, the first device patterns 222 corresponding to the partially overlap areas 212 may include a plurality of first patterns 222a and a plurality of second patterns 222b arranged randomly. The dimensions of the second patterns 222b could be the same with the dimensions of the second device patterns 224, and the dimensions of the first patterns 222a could be larger than the dimensions of the second patterns 222b. Wherein, the larger first patterns 222a arranged randomly can be used to compensate the shrink of the device patterns caused by the higher exposure intensity in the exposure step. Otherwise, the random distribution of the patterns can avoid the concentration of the large first patterns 222a.

In another embodiment, if the photo resist layer 230 is positive photo resist, and the exposure intensity corresponding to the partially overlap areas 212 is lower than the exposure intensity corresponding to the other areas in the exposure step 250, the dimensions of part of the first device patterns 222 corresponding to the partially overlap areas 212 will be designed to be smaller than the dimensions of the second device patterns 224.

In other words, referring to FIGS. 3A and 3B, the first device patterns 222 corresponding to the partially overlap areas 212 may include a plurality of first patterns 222a and a plurality of second patterns 222b arranged randomly. The dimensions of the second patterns 222b could be the same with the dimensions of the second device patterns 224, and the dimensions of the first patterns 222a could be smaller than the dimensions of the second patterns 222b. Wherein, the smaller first patterns 222a arranged randomly can be used to compensate the enlargement of the device patterns caused by the lower exposure intensity in the exposure step. Otherwise, the random distribution of the patterns can avoid the concentration of the small first patterns 222a.

Otherwise, if the photo resist layer 230 is negative photo resist, the designs of the device patterns will be contrary to said designs. Namely, if the photo resist layer 230 is negative photo resist, and the exposure intensity corresponding to the partially overlap areas 212 is higher comparatively in the exposure step of the exposure process, the dimensions of part of the first device patterns 222 corresponding to the partially overlap areas 212 can be designed to be smaller than the dimensions of the second device patterns 224. Wherein, the first device patterns 222 corresponding to the partially overlap areas 212 may include a plurality of first patterns 222a and a plurality of second patterns 222b arranged randomly. The dimensions of the second patterns 222b could be the same with the dimensions of the second device patterns 224, and the dimensions of the first patterns 222a could be smaller than the dimensions of the second patterns 222b. Consequently, the shrink of the device patterns caused by the higher exposure intensity in the exposure step cone be compensated.

Moreover, if the exposure intensity corresponding to the partially overlap areas 212 is lower comparatively in the exposure step of the exposure process, the dimensions of part of the first device patterns 222 corresponding to the partially overlap areas 212 can be designed to be larger than the dimensions of the second device patterns 224. Wherein, the first device patterns 222 corresponding to the partially overlap areas 212 may include a plurality of first patterns 222a and a plurality of second patterns 222b arranged randomly. The dimensions of the second patterns 222b could be the same with the dimensions of the second device patterns 224, and the dimensions of the first patterns 222a could be larger than the dimensions of the second patterns 222b. Consequently, the enlargement of the device patterns caused by the lower exposure intensity in the exposure step cone be compensated.

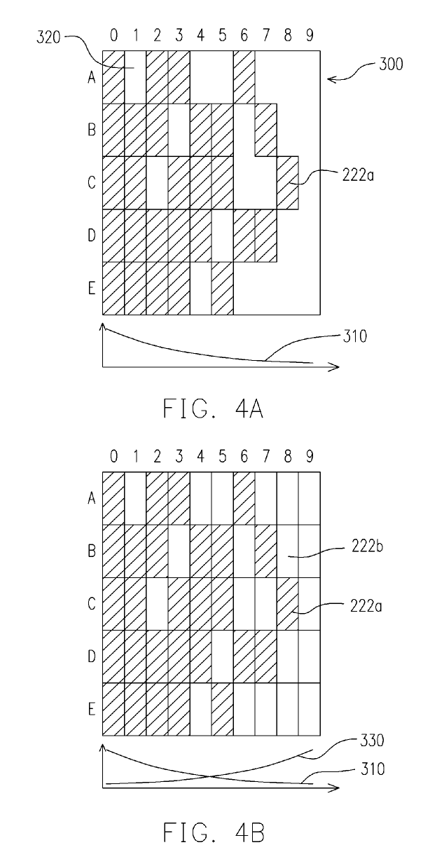

In one embodiment, the first patterns 222a and the second patterns 222b might be arranged in linear random or mosaic. FIGS. 4A and 4B are schematic drawings of the linear random arrangements of the first patterns and the second patterns.

The distribution of the first patterns 222a and the second patterns 222b in a distributing space 300 is shown in FIGS. 4A and 4B. Referring to FIG. 4A, the first patterns 222a are arranged first. The distributing density of the first patterns 222a in the distributing space 300 is set with using a distributing function 310 first. Then, the first patterns 222a are arranged randomly in the rows 0˜9 and the lines A˜E.

In one embodiment, the first patterns 222a are arranged with higher density in left than that in right by using software. The distributing function 310 and the random coefficient of each rows (rows 0˜9) are set by the software to randomly arrange the first patterns 222a. If the distributing density of the first patterns 222a in row 0 is set to be highest, the row 0 might be all filled with the first patterns 222a, and a space 320 is arranged randomly in the row 1 with lower distributing density. The amount of the spaces 320 increase from line 2 to line 9.

In detail, the locations, such as row n and line m, of the spaces 320 are decided by the software randomly. The n shown in FIG. 4A could be 1˜9, and the m shown in FIG. 4A could be A˜E. Accordingly, the layout of the distributing space 300 can be determined with the distributing function 310.

Thereafter, as shown in FIG. 4B, the spaces 320 are defined to be the locations of the second patterns 222b. Similarly, the first patterns 222b are arranged with higher density in right than that in left by using a distributing function 330. Consequently, the layout of the first patterns 222a and the second patterns 222b in the distributing space 300 is finished.

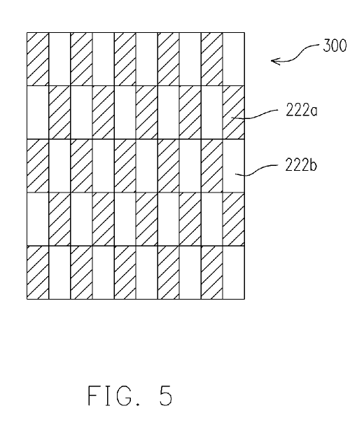

FIG. 5 is a schematic drawing of the mosaic arrangement of the first patterns and the second patterns. Referring to FIG. 5, the first patterns 222a and the second patterns 222b could be mosaic arranged to distribute evenly in the distributing space 300.

### Second Embodiment

The present invention further provides an exposure process to eliminate the areas 134 that exposed overly or exposed insufficiently shown in FIG. 2B.

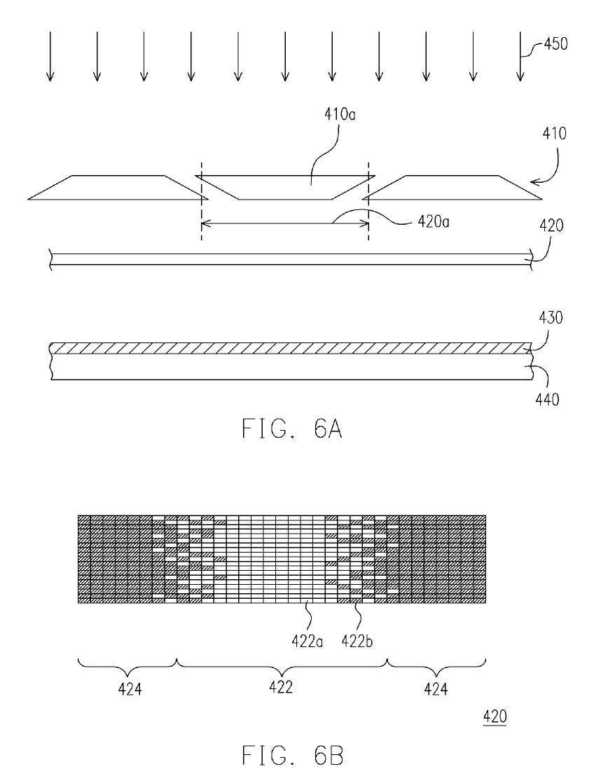

FIG. 6A is a schematic drawing of an exposure process according to another embodiment of the present invention, and FIG. 6B is a top view of a photo mask in another embodiment of the present invention.

Referring to FIGS. 3A and 3B, a plurality of optical modules 410 is provided first in this exposure process. Thereafter, a photo mask 420 is provided under the optical modules 410. Wherein, at least one of the optical modules 410 is correspondingly disposed in a central area 420a of the photo mask 420.

As shown in FIG. 6B, the photo mask 420 has a plurality of first device patterns 422 and a plurality of second device patterns 424. The first device patterns 422 are disposed in the central area 420a of the photo mask 420, and the second device patterns 424 are disposed in other area of the photo mask 420. The dimensions of parts of the first device patterns is different from the dimensions of the second device patterns. In one embodiment, the first device patterns 422 and the second device patterns 424 might be the pixel patterns of the LCDs, such as the patterns of the gates, the sources/drains or the pixel electrodes of the TFTs.

Referring to FIGS. 6A and 6B, a photo resist layer 430 is provided under the photo mask 420. The photo resist layer 430 can be positive type or negative type. Afterward, an exposure step 450 is performed for the photo resist layer 430 with using the optical modules 410 and the photo mask 420 to transfer the first device patterns 422 and the second device patterns 424 to the photo resist layer 430.

In one preferred embodiment of this invention, if the photo resist layer 430 is positive photo resist, and the exposure intensity corresponding to the central area 420a of the photo mask 420 is higher than the exposure intensity corresponding to the other areas in the exposure step 450, the dimensions of part of the first device patterns 422 corresponding to the central area 420a of the photo mask 420 will be designed to be larger than the dimensions of the second device patterns 424. The first device patterns 422 corresponding to the central area 420a of the photo mask 420 may include a plurality of first patterns 422a and a plurality of second patterns 422b arranged randomly. The dimensions of the second patterns 422b could be the same with the dimensions of the second device patterns 424, and the dimensions of the first patterns 422a could be larger than the dimensions of the second patterns 422b. Wherein, the larger first patterns 422a arranged randomly can be used to compensate the shrink of the device patterns caused by the higher exposure intensity in the exposure step.

Otherwise, if the photo resist layer 430 is positive photo resist, and the exposure intensity corresponding to the central area 420a of the photo mask 420 is lower than the exposure intensity corresponding to the other areas in the exposure step 450, the dimensions of part of the first device patterns 422 corresponding to the central area 420a of the photo mask 420 will be designed to be smaller than the dimensions of the second device patterns 424. The first device patterns 422 corresponding to the central area 420a of the photo mask 420 may include a plurality of first patterns 422a and a plurality of second patterns 422b arranged randomly. The dimensions of the second patterns 422b could be the same with the dimensions of the second device patterns 424, and the dimensions of the first patterns 422a could be smaller than the dimensions of the second patterns 422b. Wherein, the smaller first patterns 422a can be used to compensate the enlargement of the device patterns caused by the lower exposure intensity in the exposure step.

Otherwise, if the photo resist layer 430 is negative photo resist, the designs of the device patterns will be contrary to said designs. The relative description is omitted here.

Similarly, the first patterns 422a and the second patterns 422b of the photo mask 420 can be arranged in linear random or mosaic as described with referring to FIGS. 4A, 4B and 5. The relative description will be omitted here.

In summary, the present invention has the following advantages:

(1). By randomly arrangement of the device patterns with different dimensions of the photo mask, the exposure mura caused by the small optical modules can be eliminated.

(2). The present invention can be used to compensate the exposure mura caused by the different exposure intensities to improve the uniformity of the device patterns formed by the exposure process.

(3). The disadvantages of the scan-type exposure process can be easily resolved with redesigning the patterns of the photo mask, and the random distribution of the pixel patterns can be determined with software.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An exposure process, comprising:
providing a plurality of optical modules arranged in order, wherein a partially overlap area is formed between each two adjacent optical modules;
providing a photo mask under the optical modules, wherein the photo mask has a plurality of first device patterns corresponding to the partially overlap areas and a plurality of second device patterns arranging on the other area of the photo mask, and dimensions of parts of the first device patterns are different from those of the second device patterns;
providing a photo resist layer under the photo mask; and
performing an exposure step by using the optical modules and the photo mask to transfer the first device patterns and the second device patterns to the photo resist layer.

2. The exposure process according to claim 1, wherein if the photo resist layer is positive photo resist, and the exposure intensity corresponding to the partially overlap areas is higher than the exposure intensity corresponding to the other areas in the exposure step, the dimensions of part of the first device patterns corresponding to the partially overlap areas are designed to be larger than the dimensions of the second device patterns.

3. The exposure process according to claim 2, wherein the first device patterns corresponding to the partially overlap areas include a plurality of first patterns and a plurality of second patterns arranged randomly, the dimensions of the second patterns are the same with the dimensions of the second device patterns, and the dimensions of the first patterns are larger than the dimensions of the second patterns.

4. The exposure process according to claim 1, wherein if the photo resist layer is positive photo resist, and the exposure intensity corresponding to the partially overlap areas is lower than the exposure intensity corresponding to the other areas in the exposure step, the dimensions of part of the first device patterns corresponding to the partially overlap areas are designed to be smaller than the dimensions of the second device patterns.

5. The exposure process according to claim 4, wherein the first device patterns corresponding to the partially overlap areas include a plurality of first patterns and a plurality of second patterns arranged randomly, the dimensions of the second patterns are the same with the dimensions of the second device patterns, and the dimensions of the first patterns are smaller than the dimensions of the second patterns.

6. The exposure process according to claim 1, wherein if the photo resist layer is negative photo resist, and the exposure intensity corresponding to the partially overlap areas is higher than the exposure intensity corresponding to the other areas in the exposure step, the dimensions of part of the first device patterns corresponding to the partially overlap areas are designed to be smaller than the dimensions of the second device patterns.

7. The exposure process according to claim 6, wherein the first device patterns corresponding to the partially overlap areas include a plurality of first patterns and a plurality of second patterns arranged randomly, the dimensions of the second patterns are the same with the dimensions of the second device patterns, and the dimensions of the first patterns are smaller than the dimensions of the second patterns.

8. The exposure process according to claim 1, wherein if the photo resist layer is negative photo resist, and the exposure intensity corresponding to the partially overlap areas is lower than the exposure intensity corresponding to the other areas in the exposure step, the dimensions of part of the first device patterns corresponding to the partially overlap areas are designed to be larger than the dimensions of the second device patterns.

9. The exposure process according to claim 8, wherein the first device patterns corresponding to the partially overlap areas include a plurality of first patterns and a plurality of second patterns arranged randomly, the dimension of the second patterns are the same with the dimension of the second device patterns, and the dimensions of the first patterns are larger than the dimensions of the second patterns.

10. The exposure process according to claim 1, wherein the first device patterns and the second device patterns are the pixel patterns of a liquid crystal display.

11. An exposure process, comprising:
providing a plurality of optical module;
providing a photo mask under the optical modules, wherein at least one of the optical modules is correspondingly disposed in a central area of the photo mask, the photo mask has a plurality of first device patterns in the central area and a plurality of second device patterns in the other area, and dimensions of parts of the first device patterns are different from those of the second device patterns;
providing a photo resist layer under the photo mask; and
performing an exposure step by using the optical modules and the photo mask to transfer the first device patterns and the second device patterns to the photo resist layer.

12. The exposure process according to claim 11, wherein if the photo resist layer is positive photo resist, and the exposure intensity corresponding to the central areas is higher than the exposure intensity corresponding to the other areas in the exposure step, the dimensions of part of the first device patterns corresponding to the central areas are designed to be larger than the dimensions of the second device patterns.

13. The exposure process according to claim 12, wherein the first device patterns corresponding to the central areas include a plurality of first patterns and a plurality of second patterns arranged randomly, the dimensions of the second patterns are the same with the dimensions of the second device patterns, and the dimensions of the first patterns are larger than the dimensions of the second patterns.

14. The exposure process according to claim 11, wherein if the photo resist layer is positive photo resist, and the exposure intensity corresponding to the central areas is lower than the exposure intensity corresponding to the other areas in the exposure step, the dimensions of part of the first device patterns corresponding to the central areas are designed to be smaller than the dimensions of the second device patterns.

15. The exposure process according to claim 14, wherein the first device patterns corresponding to the central areas include a plurality of first patterns and a plurality of second patterns arranged randomly, the dimensions of the second patterns are the same with the dimensions of the second device patterns, and the dimensions of the first patterns are smaller than the dimensions of the second patterns.

16. The exposure process according to claim 11, wherein if the photo resist layer is negative photo resist, and the exposure intensity corresponding to the central areas is higher than the exposure intensity corresponding to the other areas in the exposure step, the dimensions of part of the first device patterns corresponding to the central areas are designed to be smaller than the dimensions of the second device patterns.

17. The exposure process according to claim 16, wherein the first device patterns corresponding to the central areas include a plurality of first patterns and a plurality of second patterns arranged randomly, the dimensions of the second patterns are the same with the dimensions of the second device patterns, and the dimensions of the first patterns are smaller than the dimensions of the second patterns.

18. The exposure process according to claim 11, wherein if the photo resist layer is negative photo resist, and the exposure intensity corresponding to the central areas is lower than the exposure intensity corresponding to the other areas in the exposure step, the dimensions of part of the first device patterns corresponding to the central areas are designed to be larger than the dimensions of the second device patterns.

19. The exposure process according to claim 18, wherein the first device patterns corresponding to the central areas include a plurality of first patterns and a plurality of second patterns arranged randomly, the dimensions of the second patterns are the same with the dimensions of the second device patterns, and the dimensions of the first patterns are larger than the dimensions of the second patterns.

20. The exposure process according to claim 11, wherein the first device patterns and the second device patterns are the pixel patterns of a liquid crystal display.
